(19) United States
(12) Patent Application Publication
(10) Pub. No.: US 2018/0342412 A1
(43) Pub. Date: Nov. 29, 2018

(54) Substrate Processing Apparatus

(71) Applicants: Kokusai Electric Semiconductor Service Inc., Toyama (JP); Kokusai Electric Corporation, Tokyo (JP)

(72) Inventors: Hideyuki MIYOSHI, Toyama (JP); Satoshi FUJII, Toyama (JP)

(21) Appl. No.: 16/052,343

(22) Filed: Aug. 1, 2018

Related U.S. Application Data
(63) Continuation of application No. PCT/JP2016/077843, filed on Sep. 21, 2016.

(30) Foreign Application Priority Data
Feb. 5, 2016 (JP) 2016-021150

(51) Int. Cl. H01L 21/677; H01L 21/67

(52) U.S. Cl. CPC H01L 21/67769; H01L 21/67754; H01L 21/67248; H01L 21/67781; H01L 21/67265; H01L 21/67772

(57) ABSTRACT

A technique capable of reducing a size of a substrate processing apparatus involves a configuration including: a process chamber where a substrate accommodated in a substrate retainer is processed; a preparation chamber configured to communicate with the process chamber; a transfer mechanism provided in the preparation chamber and configured to transfer the substrate retainer into the process chamber; and a transport mechanism provided in the preparation chamber and configured to transfer the substrate retainer to the transfer mechanism. The transport mechanism is configured to move the substrate retainer accommodating the substrate between a placement/detachment position outside of the preparation chamber and a delivery position inside of the preparation chamber. The substrate retainer is placed into and detached from the transport mechanism at the placement/detachment position, and the substrate retainer is transferred to the transfer mechanism at the delivery position.

### CROSS REFERENCE TO RELATED APPLICATIONS

This application is a continuation of International Application No. PCT/JP2016/077843, filed on Sep. 21, 2016, which claims priority under 35 U.S.C. § 119 to Application No. JP 2016-021150 filed on Feb. 5, 2016, the entire contents of which are hereby incorporated by reference.

### TECHNICAL FIELD

The present disclosure relates to a substrate processing apparatus.

### BACKGROUND

In general, a vertical type substrate processing apparatus (hereinafter also referred to as “substrate processing apparatus”) is used in a manufacturing process of a semiconductor device. For example, the substrate processing apparatus may include: a housing wherein a substrate processing is performed; and a utility box including configurations such as a device for controlling the operations of the substrate processing apparatus and a gas supply source for supplying gas to a process furnace in the housing. A pod storage chamber for temporarily storing a pod accommodating a plurality of substrates is provided in the housing.

However, the size of the above-described substrate processing apparatus may be increased.

### SUMMARY

Described herein is a technique capable of reducing the size of the substrate processing apparatus.

According to one aspect of the technique described herein, a substrate processing apparatus may include: a process chamber where a substrate accommodated in a substrate retainer is processed; a preparation chamber configured to communicate with the process chamber; a transfer mechanism provided in the preparation chamber and configured to transfer the substrate retainer into the process chamber; and a transport mechanism provided in the preparation chamber and configured to transfer the substrate retainer to the transfer mechanism, wherein the transport mechanism is configured to move the substrate retainer accommodating the substrate between a placement/detachment position outside of the preparation chamber and a delivery position inside of the preparation chamber, wherein the substrate retainer is placed into and detached from the transport mechanism at the placement/detachment position, and the substrate retainer is transferred to the transfer mechanism at the delivery position.

### BRIEF DESCRIPTION OF THE DRAWINGS

FIG. 1 schematically illustrates a substrate processing apparatus according to an embodiment described herein.

FIG. 2 schematically illustrates a vertical cross-section of the substrate processing apparatus according to the embodiment.

FIG. 3 schematically illustrates a horizontal cross-section of the substrate processing apparatus according to the embodiment.

FIG. 4 schematically illustrates a process furnace of the substrate processing apparatus according to the embodiment.

FIG. 5 schematically illustrates a substrate retainer preferably used in the substrate processing apparatus according to the embodiment.

FIG. 6 schematically illustrates a transport mechanism preferably used in the substrate processing apparatus according to the embodiment.

FIG. 7 schematically illustrates exemplary arrangement positions of first to third sensors of the transport mechanism preferably used in the substrate processing apparatus according to the embodiment.

### DETAILED DESCRIPTION

### Embodiment

Hereinafter, an embodiment of the present disclosure will be described with reference to the drawings.

### (1) Configuration of Substrate Processing Apparatus

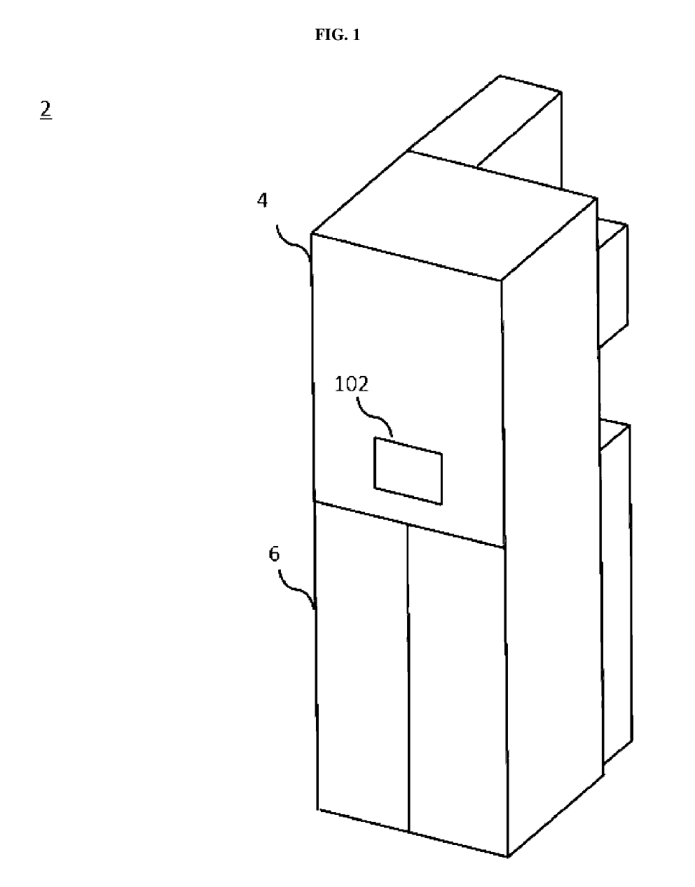

As shown in FIG. 1, a substrate processing apparatus 2 includes a housing 4 where components such as a process furnace 10 are disposed. Components such as a power supply box (not shown), a gas control box (not shown), a gas exhaust system (not shown) and an external combustion device (not shown) are provided at the back side of the housing 4. An operation device 102, which will be described later, is provided on the upper side (upper portion) of an opening/closing door 6. The opening/closing door 6 is provided on the front side of the housing 4. The opening/closing door 6 is provided at a transfer port described later.

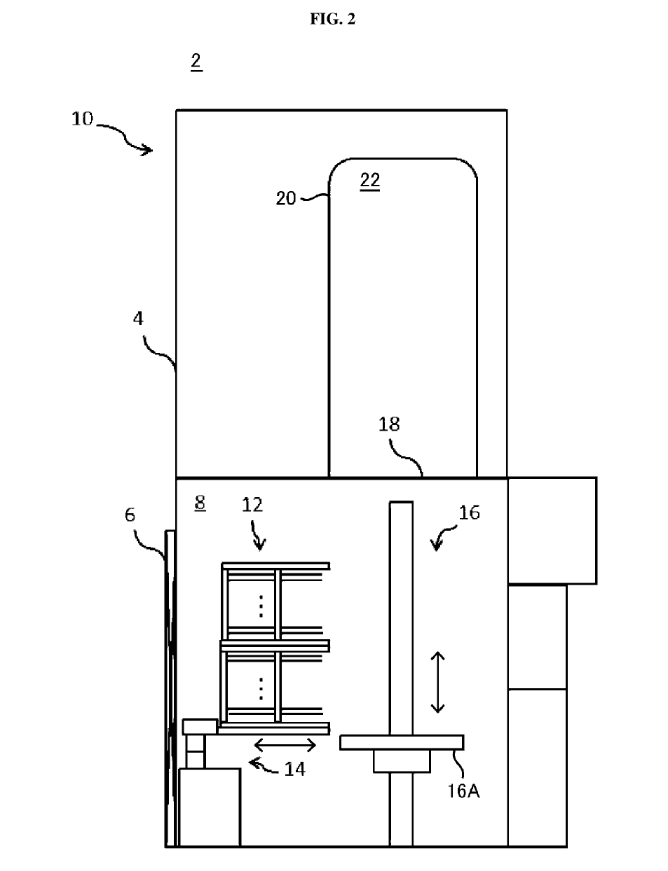

As shown in FIG. 2, the space in the housing 4 is divided into an upper space and a lower space. A preparation chamber 8 is provided in the lower space of the housing 4. The process furnace 10 described later is provided in the upper space of the housing 4. A furnace opening portion 18 is provided on a ceiling wall of the preparation chamber 8. The furnace opening portion 18 is an opening having a shape and size through which a substrate retainer 12 described later can pass. The preparation chamber 8 and the process furnace 10 (a process chamber 22 described later) are configured to communicate with each other through the furnace opening portion 18. A loading/unloading port (transfer port) for loading the substrate retainer 12 into the preparation chamber 8 and unloading the substrate retainer 12 from the preparation chamber 8 is provided on a front wall of the housing 4 so as to communicate the outside of the housing 4 with the inside of the preparation chamber 8. Wafer W is accommodated in the substrate retainer 12. The opening/closing door 6 serving as an opening/closing part (opening/closing mechanism) is provided at the loading/unloading port (transfer port). When the opening/closing door 6 is open, the substrate retainer 12 can be loaded into the preparation chamber 8 or be unloaded from the preparation chamber 8. For example, the opening/closing door 6 includes a double-open door. A locking mechanism (not shown) serving as an opening/closing control mechanism is provided at the opening/closing door 6. The locking mechanism controls the opening and closing of the opening/closing door 6. The opening and closing control of the opening/closing door 6 is performed based on the value of a temperature sensor 40 described later.

### Preparation Chamber

Operations such as an operation of placing the substrate retainer 12 described later on a transfer mechanism 16 described later (that is, an operation of placing the wafer W on the transfer mechanism 16) and an operation of detaching the substrate retainer 12 from the transfer mechanism 16 (that is, an operation of detaching the wafer W from the transfer mechanism 16) are performed in the preparation chamber 8. A transport mechanism 14 (transport device) and the transfer mechanism 16 (transfer device) are provided in the preparation chamber 8. The transport mechanism 14 is configured to transfer the substrate retainer 12 into and out of the preparation chamber 8 and is configured to transfer the substrate retainer 12 to the transfer mechanism 16. The transfer mechanism 16 is configured to transfer the substrate retainer 12 from the preparation chamber 8 into the process furnace 10 (the process chamber 22). The transport mechanism 14 is provided at the side of the opening/closing door 6 in the preparation chamber 8. For example, the transport mechanism 14 is disposed at a position along the inner side surface of the preparation chamber 8 so as to be in contact with the transfer port. The transfer mechanism 16 is provided at a position below the furnace opening portion 18, that is, at a position where the transfer mechanism 16 can pass through the furnace opening portion 18 by being moved up and down (vertically).

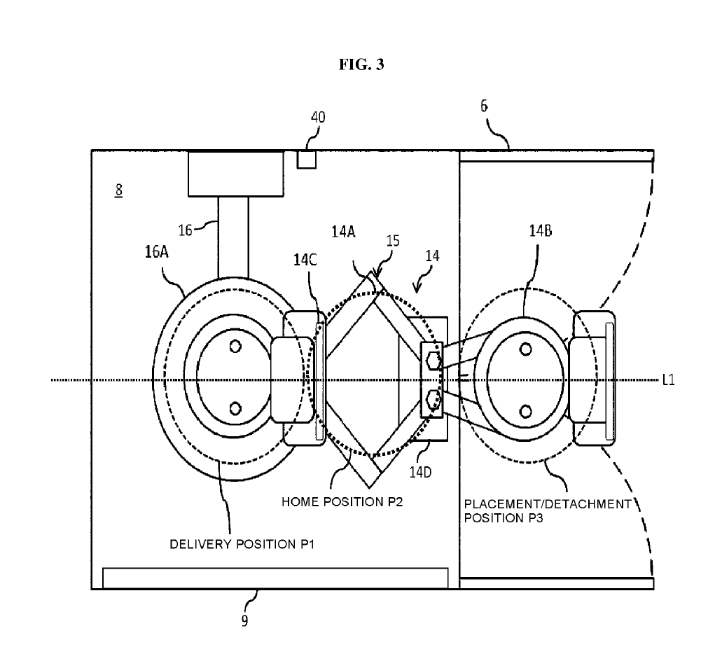

As shown in FIG. 3, the transport mechanism 14 includes a placement part (placement table) 14B that supports (places) the substrate retainer 12 described later, an arm part 15 connected to the placement part 14B and capable of moving (expanding and contracting) in the front-rear direction (horizontal direction) and a base part 14D connected to the arm part 15.

The transport mechanism 14 is configured such that the placement part 14B can be driven (horizontally movable) among at least three positions, that is, a delivery position P1, a home position P2 and a placement/detachment position P3. The transport mechanism 14 is configured to transfer the substrate retainer 12 between the delivery position P1 and the placement/detachment position P3. For example, the transport mechanism 14 is configured to transfer the substrate retainer 12 along a straight line L1 connecting the center of the delivery position P1 and the center of the placement/detachment position P3. Further, when the opening/closing door 6 is closed, the transport mechanism 14 is configured to wait at a predetermined position in the preparation chamber 8. While the transport mechanism 14 is at the predetermined position in the preparation chamber 8, the placement part 14B is located at the home position P2. The transport mechanism 14 includes a stopper (not shown) serving as a drive control mechanism. By releasing the stopper, the transport mechanism 14 can be driven.

In the specification, the delivery position P1 refers to a position of the placement part 14B inside the preparation chamber 8 when the transport mechanism 14 transfers the substrate retainer 12 on the transfer mechanism 16 (that is, on a lid portion 16A of the transfer mechanism 16 described later). The placement/detachment position P3 refers to a position of the placement part 14B outside the preparation chamber 8 when the substrate retainer 12 is detached from the transport mechanism 14 or the substrate retainer 12 is placed on the transport mechanism 14. For example, when the placement part 14B is at the placement/detachment position P3, operational personnel can place the substrate retainer 12 on the transport mechanism 14 or detach the substrate retainer 12 from the transport mechanism 14. The home position P2 (also referred to as a “standby position”) refers to a position of the placement part 14B inside the preparation chamber 8 between the delivery position P1 and the placement/detachment position P3 when the transport mechanism 14 waits at the predetermined position in the preparation chamber 8. In other words, the home position P2 refers to a position of the placement part 14B when the arm part 15 is not extended, that is, when the arm part 15 is folded. For example, the home position P2 is located above the base part 14D.

The base part 14D is provided between the delivery position P1 and the placement/detachment position P3 in the preparation chamber 8. For example, the base part 14D is provided so that the center portion (center) of the base part 14D is disposed on the above-described straight line L1.

The substrate retainer 12 can be placed on the transfer mechanism 16 (on the lid portion 16A) or be detached from the transfer mechanism 16 by cooperative operations of the transport mechanism 14 moving the substrate retainer 12 horizontally and the transfer mechanism 16 moving the substrate retainer 12 up and down as described later. Details of the transport mechanism 14 and the transfer mechanism 16 will be described later.

A clean air supply mechanism 9 serving as an air supply mechanism for supplying air (for example, air of room temperature) into the preparation chamber 8 is provided on a side wall (one side surface) of the housing 4 constituting the preparation chamber 8. An exhaust part (not shown) for exhausting the atmosphere in the preparation chamber 8 is provided at a side wall facing the side wall of the housing 4 constituting the preparation chamber 8 where the clean air supply mechanism 9 is provided. The air supplied into the preparation chamber 8 from the clean air supply mechanism 9 flows through preparation chamber 8 and is discharged through the exhaust part.

A temperature detector (temperature sensor) 40 for detecting the inner temperature of the preparation chamber 8 is provided in the preparation chamber 8 at a side facing the side wall where the clean air supply mechanism 9 is disposed. Preferably, the temperature sensor 40 is installed at the leeward side (leeward position) with respect to the air supplied from the clean air supply mechanism 9 into the preparation chamber 8. When the temperature sensor 40 is disposed at the windward side with respect to the air, the temperature sensor 40 measures the temperature of the air supplied from the clean air supply mechanism 9. As a result, the inner temperature of the preparation chamber 8 may not be accurately measured. The opening/closing door 6 is unlocked on the basis of the temperature information detected by the temperature sensor 40.

### Process Furnace

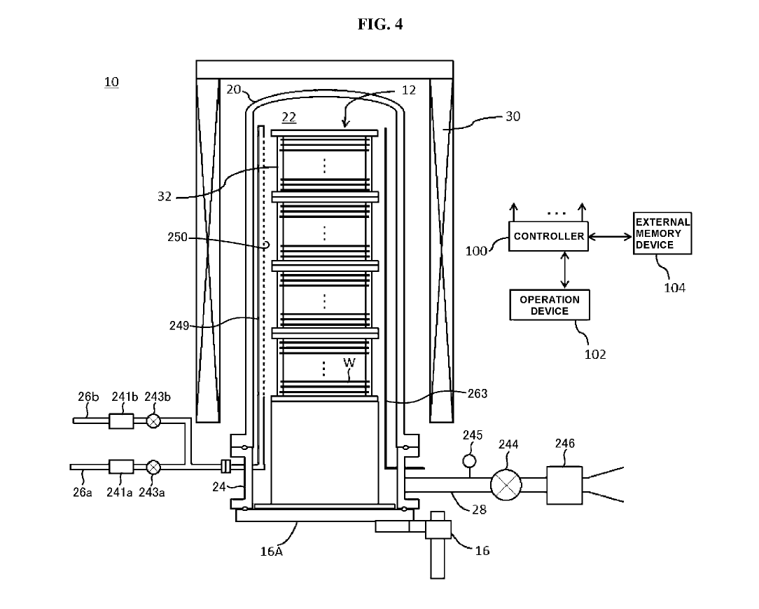

As illustrated in FIG. 4, the process furnace 10 wherein the wafer W is processed includes a heater 30 serving as a heating device (heating mechanism). The heater 30 is cylindrical, and vertically installed while being supported by a support plate (not shown). The heater 30 also functions as an activation mechanism (excitation mechanism) for activating (exciting) a gas by heat.

A reaction tube 20 is provided in and concentric with the heater 30. The reaction tube 20 is made of a heat-resistant non-metallic material such as quartz (SiO₂) and silicon carbide (SiC), and is cylindrical with a closed upper end and an open lower end. A manifold 24 is provided under and concentric with the reaction tube 20. The manifold 24 is made of a metal such as stainless steel (SUS), and cylindrical with open upper and lower ends. The upper end of the manifold 24 is engaged with the lower end of the reaction tube 20 so as to support the reaction tube 20 at the lower end portion of the reaction tube 20. A processing vessel (reaction vessel) is constituted by the reaction tube 20 and the manifold 24. The process chamber 22 is provided in the hollow cylindrical portion (inside the reaction tube 20) of the processing vessel. The process chamber 22 is capable of accommodating the wafer W.

A nozzle 249 is provided in the process chamber 22 through a sidewall of the manifold 24. A gas supply pipe 26a is connected to the nozzle 249.

An MFC (Mass Flow Controller) 241a serving as a flow rate controller (flow rate control mechanism) and a valve 243a serving as an opening/closing valve are sequentially provided at the gas supply pipe 26a from the upstream side toward the downstream side of the gas supply pipe 26a. A gas supply pipe 26b is connected to the downstream side of the valve 243a. An MFC (Mass Flow Controller) 241b serving as a flow rate controller (flow rate control mechanism) and a valve 243b serving as an opening/closing valve are sequentially provided at the gas supply pipe 26b from the upstream side toward the downstream side of the gas supply pipe 26b.

The nozzle 249 is provided in an annular space between the inner wall of the reaction tube 20 and the wafers W, and extend from bottom to top of the inner wall of the reaction tube 20 along the stacking direction of the wafers W. Specifically, the nozzle 249 is provided in a region that horizontally surrounds a wafer arrangement region where the wafers W are arranged. A plurality of gas supply holes 250 is provided at side surface of the nozzle 249. The plurality of gas supply holes 250 is open toward the center of the reaction tube 20, and configured to supply gases toward the wafers W. The plurality of gas supply holes 250 is provided to face the lower portion through the upper portion of the reaction tube 20.

A source (source gas) such as a halosilane-based gas containing silicon (Si) and halogen element as a predetermined elements (main elements) is supplied to the process chamber 22 through the MFC 241a and the valve 243a which are provided at the gas supply pipe 26a and the nozzle 249.In the specification, the source gas refers to a source in gaseous state under normal temperature and pressure and also a gas obtained by evaporating a liquid source under normal temperature and pressure. For example, a dichlorosilane (SiH₂Cl₂, abbreviated as DCS) gas may be used as the halosilane-based gas.

A reactant (hereinafter, also referred to as a “reactive gas”) having a different chemical structure (molecular structure) from the source gas is supplied into the process chamber 22 through the MFC 241b and the valve 243b which are provided at the gas supply pipe 26b and the nozzle 249. For example, oxygen (O)-containing gas may be used as the reactant. For example, an oxygen (O₂) gas may be used as the oxygen-containing gas.

An inert gas is supplied into the process chamber 22 through the MFCs 241a and 241b and the valves 243a and 243b provided at the gas supply pipes 26a and 26b, respectively, and the nozzle 249. For example, a nitrogen (N₂) gas may be used as the inert gas. The N₂ gas acts as a purge gas or a carrier gas.

The gas supply pipe 26a, the MFC 241a and the valve 243a constitute a source gas supply system. The gas supply pipe 26b, the MFC 241b the valve 243b constitute a reactant supply system. The gas supply pipes 26a and 26b, the MFCs 241a and 241b and the valves 243a and 243b constitute an inert gas supply system.

An exhaust pipe 28 for exhausting the inner atmosphere of the process chamber 22 is provided at the sidewall of the manifold 24. A vacuum pump 246 serving as a vacuum exhauster is connected to the exhaust pipe 28 through a pressure sensor 245 and an APC (Automatic Pressure Controller) valve 244. The pressure sensor 245 serves as a pressure detector (pressure detection mechanism) to detect the inner pressure of the process chamber 22, and the APC valve 244 serves as a pressure controller (pressure adjusting mechanism). With the vacuum pump 246 in operation, the APC valve 244 may be opened/closed to vacuum-exhaust the process chamber 22 or stop the vacuum exhaust. With the vacuum pump 246 in operation, the opening degree of the APC valve 244 may be adjusted based on the pressure detected by the pressure sensor 245, in order to control the inner pressure of the process chamber 22. The exhaust pipe 28, the APC valve 244 and the pressure sensor 245 constitute an exhaust system. The exhaust system may further include the vacuum pump 246.

A temperature sensor 263 serving as a temperature detector is provided in the reaction tube 20. The energization state of the heater 30 is controlled based on the temperature detected by the temperature sensor 263 such that the inner temperature of the process chamber 22 has a desired temperature distribution. The temperature sensor 263 is provided along the inner wall of the reaction tube 20.

An opening connected to the furnace opening portion 18 is provided at the lower end portion of the manifold 24. The lid portion 16A of the transfer mechanism 16 is capable of airtightly sealing the furnace opening portion 18. The lid portion 16A is also referred to as a furnace opening cover or a seal cap. The lid portion 16A is made of metal such as SUS, and is a disk-shaped. The lid portion 16A is provided outside the reaction tube 20. Specifically, the lid portion 16A is provided at the transfer mechanism 16 (hereinafter, also referred to as a boat elevator) in the preparation chamber 8. The lid portion 16A is moved up and down (vertically) by the transfer mechanism 16.

### Transfer Mechanism

The transfer mechanism 16 lowers the lid portion 16A to a position (standby position) lower than the delivery position P1 during standby before and after substrate processing. The transfer mechanism 16 lifts the lid portion 16A to the delivery position P1 when the substrate retainer 12 is transferred onto the lid portion 16A or the substrate retainer 12 is transferred from the lid portion 16A onto the transport mechanism 14. The transfer mechanism 16 is configured to load the wafer W into the process furnace 10 (process chamber 22) and unload the wafer W from the process furnace 10 (process chamber 22) by driving (i.e., moving up and down) the lid portion 16A with the substrate retainer 12 placed thereon.

### Transport Mechanism

As described above, the transport mechanism 14 includes the placement part 14B, the arm part 15 and the base part 14D.

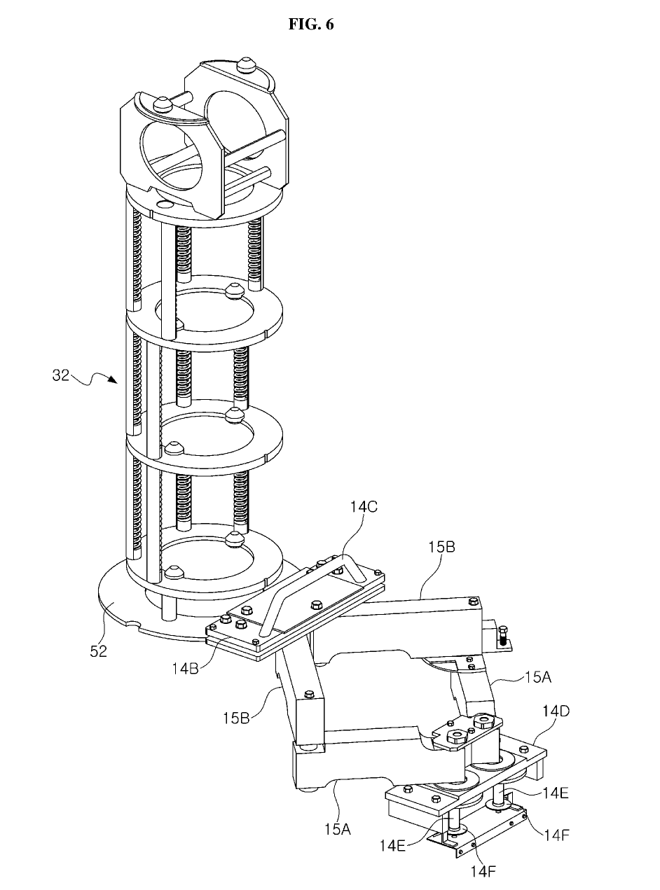

As shown in FIGS. 3 and 6, the arm part 15 includes a pair of first arms 15A and a pair of second arms 15B. The pair of first arms 15A includes a first arm on the left side and a first arm on the right side. The pair of second arms 15B includes a second arm on the left side and a second arm on the right side. The first arms 15A are also referred to as lower arms or a first arm part. The second arms 15B are also referred to as upper arms or a second arm part. The arm part 15 is configured to be line-symmetric (symmetric) with respect to the above-mentioned straight line L1 when viewed from above.

The lower end portions of the lower arms 15A are disposed on the base part 14D, for example, near the center of the base part 14D. The lower end portion of each of the lower arms 15A is connected so as to be rotatable with respect to the base part 14D via a shaft 14E. The upper end portion of each of the lower arms 15A is connected to the lower end portion of the corresponding one of the upper arms 15B. The upper end portion of each of the lower arms 15A and the lower end portion of the corresponding one of the upper arms 15B are rotatably connected to each other via a shaft, for example. That is, the upper arms 15B are rotatably connected to the lower arms 15A. The lower arms 15A are connected to the upper arms 15B at two connecting portions. Each of the lower arms 15A rotates in a direction opposite to that of the corresponding one of the upper arms 15B and by an angle substantially same as that of the corresponding one of the upper arms 15B with respect to one of the two connecting portions as a reference point. The upper end portion of each of the upper arms 15B is disposed on and rotatably connected to the placement part 14B by a component such as a shaft.

The arm part 15 is configured to be rotatable (bendable) with respect to a pair of connecting portions connecting the lower arms 15A and the upper arms 15B as the reference points. Thus, the arm part 15 can extend and retract in both front and rear directions with respect to the base part 14D. As a result, the transport mechanism 14 can move placement part 14B along the straight line L1.

The placement part 14B is installed on the upper end portions of the upper arms 15B so as to protrude therefrom (i.e., from the side opposite to the connecting portions between the upper arms 15B and the lower arms 15A). Thereby, the substrate retainer 12 can be transferred from the placement part 14B to the transfer mechanism 16 without interfering with the arm part 15.

A grip part 14C that drives (moves) the placement part 14B backward and forward is provided on the placement part 14B. For example, the grip part 14C is disposed so as to be line-symmetric with respect to the straight line L1. By pushing and pulling the grip part 14C by the operational personnel, the placement part 14B can be moved in the forward and backward directions while holding the placement part 14B horizontally. It is preferable that the grip part 14C is vertically provided so that the operational personnel can pick up the grip part 14C at the front side on the placement part 14B (a position close to the transfer port). Thus, the operational personnel can easily push or pull the grip part 14C. As a result, while moving the placement part 14B, it is possible to prevent the operational personnel from touching the substrate retainer 12 on the placement part 14B, and it is also possible to prevent the substrate retainer 12 from being displaced or falling over.

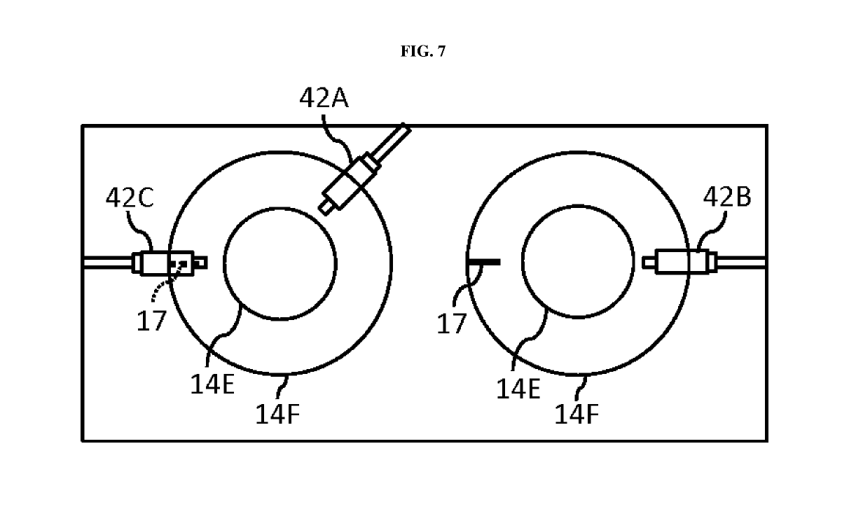

As shown in FIG. 7, the transport mechanism 14 includes a first sensor 42A, a second sensor 42b and a third sensor 42c, which are serving as position sensors for detecting the position of the placement part 14B. The first sensor 42A detects whether the placement part 14B is positioned at the delivery position P1. The first sensor 42A is also referred to as a delivery position detecting sensor. The second sensor 42B detects whether the placement part 14B is positioned at the home position P2. The second sensor 42B is also referred to as a home position detecting sensor. The third sensor 42C detects whether the placement part 14B is positioned at the placement/detachment position P3. The third sensor 42C is also referred to as a placement/detachment position detecting sensor. Each of the first through third sensors 42A through 42C is constituted by, for example, an optical sensor.

The first through third sensors 42A through 42C are provided at positions that can detect a plate-shaped part 14F serving as a detection part connected to the above-described shaft 14E, respectively. In the present embodiment, the plate-shaped part 14F is installed on each of the pair of shafts 14E, respectively. However, the plate-shaped part 14F may be installed on any one of the pair of shafts 14E. When the plate-shaped part 14F is provided under the shaft 14E, (for example, when the shaft 14E penetrates the base part 14D and the plate-shaped part 14F is connected to the shaft 14E below the base part 14D), the first through third sensors 42A through 42C are provided on the base part 14D, for example, on the back surface of the base part 14D.

The plate-shaped part 14F is disk-shaped and a mark 17 is attached at a predetermined position of the plate-shaped part 14F. When the placement part 14B is moved, the shaft 14E rotates. The rotation amount of the shaft 14E is proportional (dependent) to the movement amount (movement distance) of the placement part 14B. By providing the first through third sensors 42A through 42C at different positions (along the circumferential direction of the plate-shaped part 14 F) and detecting the position of the mark 17 of the plate-shaped part 14F by the first through third sensors 42A through 42C when the placement part 14B is moved by the rotation of the shaft 14E, the position of the placement part 14B can be detected.

For example, in the present embodiment, a reference position is set to a position of the placement part 14B when the placement part 14B is located at the home position P2, that is, the rotation amount of the shaft 14E is zero. The positioning of the plate-shaped part 14F is performed such that the mark 17 of the plate-shaped part 14F reaches to the position when the rotation amount of the shaft 14E is zero. When two plate-shaped parts 14F are provided in the present embodiment, the two plate-shaped parts 14F are aligned such that the marks 17 of the respective plate-shaped parts 14F are coincide with each other when the two plate-shaped parts 14F are overlapped with each other. The second sensor 42B is installed at a position that can detect whether the mark 17 of the plate-shaped part 14F is at the reference position. When the placement part 14B is moved from the home position P2 to the delivery position P1, the pair of shafts 14E rotates in opposite directions by equal angles. In accordance with the rotation of the pair of shafts 14E, the plate-shaped part 14F is rotated and the position of the mark 17 of the plate-shaped part 14F is changed. The first sensor 42A is installed at a position that can detect the mark 17 of the plate-shaped part 14F when the placement part 14B is moved to the delivery position P1. Likewise, the third sensor 42C is installed at a position that can detect the mark 17 on the plate-shaped part 14F when the placement part 14B is moved to the placement/detachment position P3. As a result, by the first through third sensors 42A through 42C, it is possible to detect where the placement part 14B is located among the delivery position P1, the home position P2 and the placement/detachment position P3.

### Connection Part

As shown in FIG. 6, when the substrate retainer 12 is transferred between the transport mechanism 14 and the transfer mechanism 16, the substrate retainer 12 is delivered using a connection part 52. The connection part 52 includes a circular plate-shaped (disk-shaped) upper surface portion supported by the placement part 14B, a lower surface portion engaged with the lid portion 16A and a column portion connecting the upper surface portion and the lower surface portion. A space wherethrough the placement part 14B can move back and forth is provided between the upper surface portion and the lower surface portion. The connection part 52 is placed on the lid portion 16A except when it is used to deliver the substrate retainer 12.

### Substrate Retainer

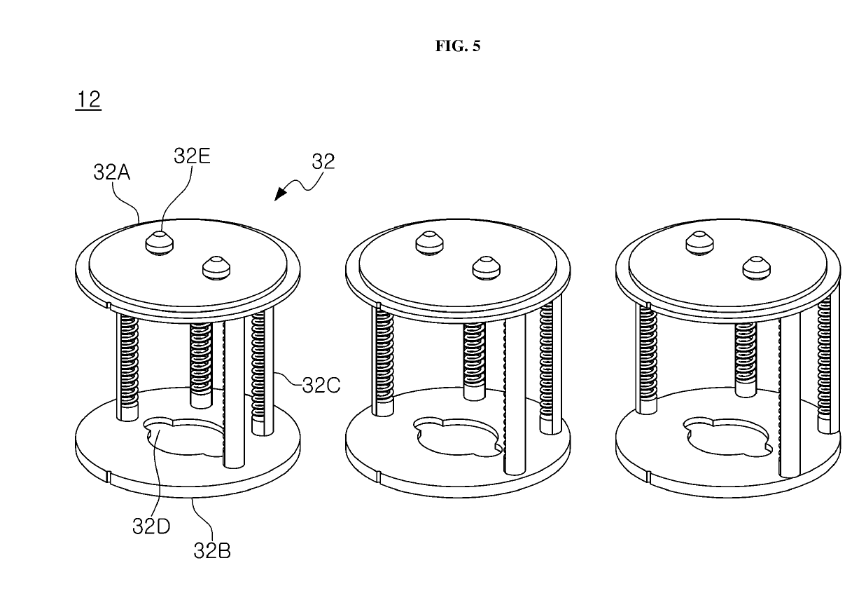

As shown in FIGS. 4 and 5, according to the present embodiment, small retainers (cassettes) 32 for accommodating (for example, 25) wafers W are used as the substrate retainer 12. The substrate retainer 12 is configured by stacking the cassettes 32 vertically in multi-stages. The cassette 32 is constituted by a top plate 32A, a bottom plate 32B and a column portion 32C with a plurality of holding grooves for supporting the wafers W. A plurality of holding grooves for supporting the wafers W is provided at the column portion 32C. A hole 32D for aligning the cassette 32 is provided in the bottom plate 32B. A projection 32E engaging with the hole 32D is provided in the top plate 32A.

The installation position of the column portion 32C of the cassette 32 may vary depending on the size (diameter in inches) of the wafer W. Further, the number and position of the holding grooves provided at the column portion 32C may vary depending on the thickness of the wafer W in the cassette 32. The shape and dimensions of the cassette 32 may vary depending on the characteristics of the wafers W such as the sizes and thicknesses of the wafers W. However, by making the structure of the top plate 32A of the cassettes 32 compatible with that of the bottom plate 32B of the cassettes 32, different kinds of the cassettes 32 can be stacked to serve as the substrate retainer 12. Thus, it is possible to simultaneously process wafers W of different types (wafers having different sizes and thicknesses) accommodated in the different kinds of the cassettes.

A tray (not shown) in the same shape as the wafer W may be provided at the cassette 32. The tray is made of, for example, silicon. By placing a broken or deficient substrate on the tray, it is possible to perform a desired process on the substrate broken or the substrate having the missing portion.

While the cassette for accommodating the horizontally placed substrates stacked in the vertical direction has been described in the above-described embodiment, the above-described embodiment is not limited thereto. For example, a cassette for accommodating vertically placed substrates stacked in the horizontal direction can also be used in the above-described embodiment. The cassettes for accommodating vertically placed substrates stacked in the horizontal direction can be stacked vertically by providing a common structure including the projections 32E and the holes 32D on the upper and lower contact surfaces (i.e., on the top plate 32A and the bottom plates 32B) of the cassettes for accommodating vertically placed substrates stacked in the horizontal direction. Further, a cassette for accommodating vertically placed substrates can be stacked vertically on a cassette for accommodating the horizontally placed substrates by providing a common structure at the upper and lower contact surfaces between the cassette for accommodating vertically placed substrates and the cassette for accommodating the horizontally placed substrates.

A controller 100 serving as a control device (control mechanism) is embodied by a microprocessor (computer) including a CPU (Central Processing Unit) (not shown), a RAM (Random Access Memory) (not shown), a memory device (not shown) and an I/O port (not shown). The RAM, the memory device and the I/O port may exchange data with the CPU through an internal bus (not shown). For example, the operation device (I/O device) 102 such as a touch panel is connected to the controller 100.

The memory device is embodied by components such as a flash memory and HDD (Hard Disk Drive). A control program for controlling the operation of the substrate processing apparatus 2 or a process recipe containing information on the sequence and conditions of a substrate processing described later is readably stored in the memory device. The process recipe is obtained by combining steps of the substrate processing described later such that the controller 100 may execute the steps to acquire a predetermine result, and functions as a program. Hereafter, the process recipe and the control program are collectively referred to as a program. The process recipe is simply referred to as a recipe. In this specification, “program” may indicate only the recipe, indicate only the control program, or indicate both of them. The RAM is a work area where a program or data read by the CPU is temporarily stored.

The I/O port is connected to the above-described components such as the transport mechanism 14, the transfer mechanism 16, the MFCs 241a and 241b, the valves 243a and 243b, the pressure sensor 245, the APC valve 244, the vacuum pump 246, the heater 30, the temperature sensors 40 and 263, the first sensor 42A, the second sensor 42B, the third sensor 42C and the locking mechanism.

The CPU is configured to read a control program from the memory device and execute the read control program. Furthermore, the CPU is configured to read a recipe from the memory device according to an operation command inputted from the I/O device 102. According to the contents of the read recipe, the CPU may be configured to control various operations such as flow rate adjusting operations for various gases by the MFCs 241a and 241b, opening/closing operations of the valves 243a and 243b, an opening/closing operation of the APC valve 244, a pressure adjusting operation by the APC valve 244 based on the pressure sensor 245, a start and stop of the vacuum pump 246, a temperature adjusting operation of the heater 30 based on the temperature sensor 263, an unlocking operation of the opening/closing door 6 based on the temperature sensor 40 and an elevating operation of the cassette 32 by the transfer mechanism 16.

The controller 100 may be embodied by installing the above-described program stored in an external memory device 104 serving as a recording medium into a computer, the external memory device 104 including a magnetic disk such as a hard disk, an optical disk such as CD, a magneto-optical disk such as MO, and a semiconductor memory such as a USB memory. The memory device or the external memory device 104 may be embodied by a non-transitory computer readable recording medium. Hereafter, the memory device and the external memory device 104 are collectively referred to as recording media. In this specification, “recording media” may indicate only the memory device, indicate only the external memory device 104, and indicate both of the memory device and the external memory device 104. Instead of the external memory device 104, a communication means such as the Internet and dedicated line may be used as the means for providing a program to a computer.

### (2) Substrate Processing

Next, an exemplary process (film-forming process) for forming a film on the wafer W serving as a substrate, which is one of semiconductor device manufacturing processes, using the substrate processing apparatus 2 according to the embodiment is described. Hereinafter, an example of forming a silicon oxide film (SiO₂ film) on the wafer W by supplying DCS gas as the source gas and O₂ gas as the reactive gas to the wafer W will be described. In the following description, the operations the components constituting the substrate processing apparatus 2 are controlled by the controller 100.

### First Transfer Step

In a first transfer step, a preparation step, a placement step and a delivery step are performed sequentially.

### Preparation Step

After confirming that the inner temperature of the preparation chamber 8 detected by the temperature sensor 40 is lower than a predetermined temperature (for example, 50° C.) and that the locking of the opening/closing door 6 is released, the opening/closing door 6 is opened. When the inner temperature of the preparation chamber 8 detected by the temperature sensor 40 is equal to or higher than the predetermined temperature, the lock of the opening/closing door 6 is not released and the opening/closing door 6 cannot be opened.

After the opening/closing door 6 is opened, the lid portion 16A located at a position (the standby position) lower than the delivery position P1 is raised (lifted) to the delivery position P1 by the transfer mechanism 16. The connection part 52 is placed on the lid portion 16A. The stopper is released and the placement part 14B is moved to the delivery position P1 by the transport mechanism 14. At this time, the placement part 14B is inserted into the space of the connection part 52 to fix the stopper. When the first sensor 42A detects that the placement part 14B has reached (positioned) at the delivery position P1, the lid portion 16A is lowered to the standby position by the transfer mechanism 16 and the connection part 52 on the lid portion 16A is transferred to the placement part 14B. That is, the connection part 52 is placed on the placement part 14B. When the first sensor 42A detects that the placement part 14B has not reached (positioned) at the delivery position P1, the transfer mechanism 16 is prevented from being driven.

### Placement Step

After placing the connection part 52 on the placement part 14B, the stopper is released. The operational personnel holds the grip part 14C and moves the placement part 14B to the placement/detachment position P3 via the home position P2. The stopper is fixed at the placement/detachment position P3, and the substrate retainer 12 accommodating the wafer W is placed on the transport mechanism 14, that is, on the placement part 14B (i.e., on the connection part 52). In other words, the cassettes including the cassette 32 accommodating the wafers W are stacked in the vertical direction on the placement part 14B.

### Delivery Step

After the substrate retainer 12 is placed on the transport mechanism 14 (i.e., on the placement part 14B), the substrate retainer 12 (the cassettes including the cassette 32) is transferred from the placement/detachment position P3 to the delivery position P1 with the cassettes including the cassette 32 are stacked vertically by releasing the stopper and moving the placement part 14B to the delivery position P1. After the placement part 14B reaches the delivery position P1, the stopper is fixed. When the first sensor detects that the placement part 14B has reached the delivery position P1, the lid portion 16A is raised to the delivery position P1 by the transfer mechanism 16. After the lid portion 16A is raised to the delivery position P1, the substrate retainer 12 is transferred from the transport mechanism 14 to the transfer mechanism 16 at the delivery position P1. That is, the connection part 52 and the substrate retainer 12 placed on the connection part 52 are transferred from the placement part 14B onto the lid portion 16A. After transferring the substrate retainer 12 to the transfer mechanism 16, the stopper is released. Then the placement part 14B is retracted to the home position P2, the stopper is fixed at the home position P2 and the opening/closing door 6 is closed and locked.

### Substrate Processing Step

In a substrate processing step, a loading step, a film-forming step and an unloading step are performed sequentially.

### Loading Step

When the second sensor 42B detects that the placement part 14B is located at the home position P2, the transfer mechanism 16 is driven. The substrate retainer 12 (the cassettes including the cassette 32) is raised (lifted) by the transfer mechanism 16 and loaded into the process chamber 22 from the preparation chamber 8 (boat loading). In this state, the lid portion 16A seals the lower end opening (the furnace opening portion 18) of the manifold 24.

### Film-Forming Step

The vacuum pump 246 vacuum-exhausts the process chamber 22 such that the inner pressure of the process chamber 22, i.e., the pressure of the space in which the wafers W are present is set to a desired pressure (vacuum level). At this time, the inner pressure of the process chamber 22 is measured by the pressure sensor 245, and the APC valve 244 is feedback controlled based on the measured pressure. The heater 30 heats the process chamber 22 such that the temperature of the wafers W in the process chamber 22 becomes a desired temperature. The energization state of the heater 30 is feedback controlled based on the temperature detected by the temperature sensor 263 such that the inner temperature of the process chamber 22 has a desired temperature distribution.

DCS gas and O₂ gas are supplied to the wafer W in the process chamber 22 through the gas supply pipes 26a and 26b while heating and exhausting the inside of the process chamber 22. As a result, a SiO₂ film is formed on the surface of the wafer W.

### Unloading Step

After the film-forming step is complete, that is, after the film having a desired thickness is formed on the wafer W, the inert gas serving as the purge gas is supplied into the process chamber 22 through the gas supply pipes 26a and 26b. Thus, the inner atmosphere of the process chamber 22 is replaced with the inert gas. The inner pressure of the process chamber 22 is returned to normal pressure (atmospheric pressure).

Thereafter, the lid portion 16A is lowered by the transfer mechanism 16, the lower end of the manifold 24 is opened, and the processed wafer W supported by the substrate retainer 12 is unloaded from the process chamber 22 into the preparation chamber 8 (boat unloading).

### Second Transfer Step

When the inner temperature of the preparation chamber 8 detected by the temperature sensor 40 is lower than a predetermined temperature (for example, 50° C.), the lock of the opening/closing door 6 is released and the opening/closing door 6 is opened. Thereafter, the substrate retainer 12 is unloaded to the outside of the substrate processing apparatus 2 in the order reverse to that of the first transfer step.

As described above, the substrate processing by the substrate processing apparatus 2 according to the present embodiment is completed.

### (3) Effects According to the Embodiment

According to the embodiment, one or more advantageous effects described below are provided.

(a) The substrate processing apparatus according to the embodiment can be configured without some components such as a pod storage chamber and a wafer transport device installed in the conventional apparatus. As a result, the space required for the substrate processing apparatus according to the embodiment can be reduced and the size of the substrate processing apparatus according to the embodiment can be reduced. Further, the substrate processing apparatus according to the embodiment can be configured by omitting the structure of the driving system such as the wafer transport device and a pod transfer device installed in the conventional apparatus. As a result, the structure of the substrate processing apparatus according to the embodiment can be simplified and the operation cost such as a maintenance cost can be reduced according to the embodiment. Furthermore, when replacing the old equipment (existing apparatus) with the substrate processing apparatus according to the embodiment, the area for installing the substrate processing apparatus can be estimated more easily.

(b) According to the embodiment, the substrate retainer is constituted by the stacking cassettes in multi-stages. Thus, the substrate processing apparatus according to the embodiment can process any given number of wafers by setting the number of the stacked cassettes constituting the substrate retainer. This makes it possible to flexibly cope with various production modes such as multi-item small-quantity production, thus the productivity can be improved.

(c) According to the embodiment, the cassettes are adapted to the characteristics of the substrate such as shape, size (in inches), thickness and outer diameter. However, by providing a common structure of the portions (upper and lower contact surfaces) necessary for stacking the cassettes, it is possible to process various kinds of substrates at the same time and to process a various kinds of substrates of multi-item small-quantity production.

(d) It is possible to process the substrates while supporting the substrates in the vertical direction in the vertical type substrate processing apparatus, the slipping of the wafer can be suppressed.

### Other Embodiments

While the technique is described by way of the above-described embodiment, the above-described technique is not limited thereto. The above-described technique may be modified in various ways without departing from the gist thereof.

While the embodiment is described by way of an example in which the cassettes including the cassette 32 stacked in the vertical direction serving as the substrate retainer 12 are transferred by the transport mechanism 14, the above-described technique is not limited thereto. For example, the above-described technique may be applied when only one cassette out of a plurality of cassettes is used as the substrate retainer 12.

While the embodiment is described by way of an example in which an oxide film (SiO₂ film) is formed on the wafer W, the above-described technique is not limited thereto. For example, the above-described technique may be applied to the formations of a film such as a metal-based film and a nitride film. The above-described technique may also be applied to the processes such as an oxidation process, a diffusion process, an annealing process and an etching process.

While a substrate processing apparatus having a hot wall type process furnace is exemplified in the above-described embodiment, the above-described technique is not limited thereto. For example, the above-described technique may be applied the film formation using a substrate processing apparatus having cold wall type process furnace.

The film formations using the substrate processing apparatus including the cold wall type process furnace may be performed according to the processing sequences and the processing conditions same as those of the above-described embodiments, and the same advantageous effects can be obtained.

The above-described embodiments may be appropriately combined. The processing sequences and the processing conditions of the combinations may be substantially the same as those of the above-described embodiment.

According to the technique described herein, the size of the substrate processing apparatus can be reduced.

What is claimed is:

1. A substrate processing apparatus, comprising:
a process chamber where a substrate accommodated in a substrate retainer is processed;
a preparation chamber configured to communicate with the process chamber;
a transfer mechanism provided in the preparation chamber and configured to transfer the substrate retainer into the process chamber; and
a transport mechanism provided in the preparation chamber and configured to transfer the substrate retainer to the transfer mechanism,
wherein the transport mechanism is configured to move the substrate retainer accommodating the substrate between a placement/detachment position outside of the preparation chamber and a delivery position inside of the preparation chamber, wherein the substrate retainer is placed into and detached from the transport mechanism at the placement/detachment position, and the substrate retainer is transferred to the transfer mechanism at the delivery position.

2. The substrate processing apparatus of claim 1, wherein the transport mechanism is configured to transfer the substrate retainer along a straight line connecting the placement/detachment position and the delivery position.

3. The substrate processing apparatus of claim 2, wherein the transport mechanism comprises:
a placement part whereon the substrate retainer is placed;
an arm part connected to the placement part; and
a base part connected to the arm part.

4. The substrate processing apparatus of claim 3, wherein the base part is provided in the preparation chamber between the placement/detachment position and the delivery position.

5. The substrate processing apparatus of claim 3, wherein the arm part comprises:
a pair of first arms wherein one end portion of each of the pair of the first arms is connected to the base part; and
a pair of second arms wherein one end portion of each of the pair of the second arms is connected to the other end portion of either of the pair of the first arms, and the other end portion of each of the pair of the second arms is connected to the placement part,
wherein the pair of the first arms and the pair of the second arms are configured to be rotatable with respect to connecting portions as reference points wherein the pair of the first arms are connected to the pair of the second arms at the connecting portions.

6. The substrate processing apparatus of claim 5, wherein the pair of first arms and the pair of second arms are configured to rotate with respect to a pair of the connecting portions as the reference points such that each of the pair of first arms rotates by an angle substantially same as that of either of the pair of second arms.

7. The substrate processing apparatus of claim 3, wherein the transport mechanism comprises a sensor part configured to detect a position of the placement part.

8. The substrate processing apparatus of claim 7, wherein the sensor part comprises:
a first sensor configured to detect whether the placement part is positioned at the placement/detachment position;
a second sensor configured to detect whether the placement part is positioned at the delivery position; and
a third sensor configured to detect whether the placement part is positioned at a standby position inside the preparation chamber.

9. The substrate processing apparatus of claim 1, further comprising:
an air supply mechanism provided at a side wall of a housing of the preparation chamber and configured to supply air into the preparation chamber; and
a temperature sensor provided at leeward position with respect to the air supplied from the air supply mechanism and configured to detect inner temperature of the preparation chamber.

10. The substrate processing apparatus of claim 9, further comprising:
an opening/closing mechanism provided at a transfer port disposed at a front wall of the housing wherein the substrate retainer is loaded into the preparation chamber or unloaded from the preparation chamber through the transfer port,
wherein the opening/closing mechanism is opened when the inner temperature detected by the temperature sensor is lower than a predetermined temperature.
